(19) United States
(12) Patent Application Publication
(10) Pub. No.: US 2016/0216308 A1
(43) Pub. Date: Jul. 28, 2016

(54) DIAGNOSIS AND POSITION IDENTIFICATION FOR REMOTE CAPACITOR BANKS

(71) Applicants: Carl L. Benner, Bryan, TX (US); Karthick Muthu-Manivannan, College Station, TX (US); Alexandre Perrera-Lluna, Barcelona (ES); Peng Xu, College Station, TX (US); Billy Don Russell, College Station, TX (US)

(72) Inventors: Carl L. Benner, Bryan, TX (US); Karthick Muthu-Manivannan, College Station, TX (US); Alexandre Perrera-Lluna, Barcelona (ES); Peng Xu, College Station, TX (US); Billy Don Russell, College Station, TX (US)

(21) Appl. No.: 15/089,189

(22) Filed: Apr. 1, 2016

Related U.S. Application Data
(63) Continuation of application No. 12/347,105, filed on Dec. 31, 2008, now abandoned.

(51) Int. Cl. G01R 31/02; G01R 31/40

(52) U.S. Cl. CPC G01R 31/028; G01R 31/40

(57) ABSTRACT

A method of evaluating one or more capacitor banks in an electrical power system includes: (a) acquiring data representing a signal of interest of the power system, where the data describes a plurality of power system events; and (b) based on one or more patterns contained in the data, identifying at least one of the power system events as being associated with capacitor operation.

### BACKGROUND OF THE INVENTION

The present invention relates generally to a method for analyzing an electrical power system, and more particularly to a method for diagnosing capacitor banks in such power systems.

Capacitor banks are common devices in power distribution grids. They provide corrections for reactive power, thereby improving power factors, providing voltage support, reducing line losses, and lowering the current drawn from the power supply line. In order to obtain a good power correction, banks of various sizes are placed along the line supplied by each feeder. The size and placement of these depends on the magnitude of the desired correction, which in turn, is a function of the load sustained by the circuit. Tracking the performance and activity of these capacitor banks in distribution systems is a challenging task due to their high number and the widespread geographical distribution of the feeder circuits. Capacitor banks have numerous failure modes and they fail rather often, compared to other line apparatus. Ramifications of these failures range from a loss of the support that the banks provide, to more severe power quality problems that cause significant transients, which can damage other line apparatus and customer loads.

### BRIEF SUMMARY OF THE INVENTION

These and other shortcomings of the prior art are addressed by the present invention, which according to one aspect may provide a method of evaluating one or more capacitor banks in an electrical power system. The method may include: (a) acquiring data representing a signal of interest of the power system, where the data describes a plurality of power system events; and (b) based on one or more patterns contained in the data, identifying at least one of the power system events as being associated with a capacitor operation.

According to another aspect of the invention, the method may further include classifying the capacitor operation as normal or abnormal.

According to another aspect of the invention, the method may further include (a) extracting at least one feature characteristic of a capacitor operation from the data; and (b) identifying one or more capacitor banks as potentially being involved in the at least one capacitor operation, based at least in part on the at least one extracted feature.

According to another aspect of the invention, the at least one extracted feature may be a voltage transient consistent with capacitor bank switch contacts alternately making and breaking connection several times per second.

According to another aspect of the invention, the one or more capacitor banks may include at least one capacitor for each of a plurality of phases, and the at least one extracted feature may be a volt-ampere reactive power step size for each phase that occurs during a capacitor operation.

According to another aspect of the invention, the capacitor bank may include at least one capacitor for each of a plurality of phases, and the at least one extracted feature may be a sequence in which the phases switch on or off

According to another aspect of the invention, the capacitor bank may include at least one capacitor for each of a plurality of phases, and the at least one extracted feature may be a time interval between the phases when the phases switch on or off

According to another aspect of the invention, step (a) may include extracting a plurality of features from the data, and step (b) may include grouping the extracted features into one or more clusters, wherein each cluster represents a repeated event occurring at a specific capacitor bank.

According to another aspect of the invention, the data may be taken from multiple geographic monitoring points in the electrical power system.

According to another aspect of the invention, the data may include information as to whether the power system events have occurred upstream or downstream relative to each of the monitoring points.

According to another aspect of the invention, the method may further include: (a) counting the number of capacitor operations over a defined period of time; (b) comparing the number of operations to a predetermined limit; and (c) classifying the operations as abnormal if the predetermined limit is exceeded.

According to another aspect of the invention, the method may further include: (a) measuring the frequency of capacitor operations over a defined period of time; (b) comparing the frequency of operations to a predetermined limit; and (c) classifying the operations as abnormal if the predetermined limit is exceeded.

According to another aspect of the invention, a computer program product may include one or more computer readable media having stored thereon a plurality of instructions that, when executed by one or more processors of a system, causes the one or more processors to carry out a method which may include: (a) acquiring data representing a signal of interest of the power system, where the data describes a plurality of power system events; and (b) based on one or more patterns contained in the data, identifying at least one of the power system events as being associated with a capacitor operation.

According to another aspect of the invention, the instructions may further cause the one or more processors to classify the capacitor operation as normal or abnormal.

According to another aspect of the invention, the instructions may further cause the one or more processors to: (a) extract at least one feature characteristic of a capacitor operation from the data; and (b) identify one or more capacitor banks as potentially being involved in the at least one capacitor operation, based at least in part on the at least one extracted feature.

According to another aspect of the invention, the at least one extracted feature may be a voltage transient consistent with capacitor bank switch contacts alternately making and breaking connection several times per second.

According to another aspect of the invention, the one or more capacitor banks may include at least one capacitor for each of a plurality of phases, and the at least one extracted feature may be a volt-ampere reactive power step size for each phase that occurs during a capacitor operation.

According to another aspect of the invention the capacitor bank may include at least one capacitor for each of a plurality of phases, and the at least one extracted feature may be a sequence in which the phases switch on or off

According to another aspect of the invention, the capacitor bank may include at least one capacitor for each of a plurality of phases, and the at least one extracted feature may be a time interval between the phases when the phases switch on or off

According to another aspect of the invention, step (a) may include extracting a plurality of features from the data, and step (b) may include grouping the extracted features into one or more clusters, wherein each cluster represents a repeated event occurring at a specific capacitor bank.

According to another aspect of the invention, the data may be taken from multiple geographic monitoring points in the electrical power system.

According to another aspect of the invention, the data may include information as to whether the power system events have occurred upstream or downstream relative to each of the monitoring points.

According to another aspect of the invention, the instructions may further cause the one or more processors to: (a) count the number of capacitor operations over a defined period of time; (b) compare the number of operations to a predetermined limit; and (c) classify the operations as abnormal if the predetermined limit is exceeded.

According to another aspect of the invention, the instructions may further cause the one or more processors to: (a) measure the frequency of capacitor operations over a defined period of time; (b) compare the frequency of operations to a predetermined limit; and (c) classify the operations as abnormal if the predetermined limit is exceeded.

### BRIEF DESCRIPTION OF THE DRAWINGS

The subject matter that is regarded as the invention may be best understood by reference to the following description taken in conjunction with the accompanying figures in which:

FIG. 1 is a schematic diagram of a portion of an electrical power system;

FIG. 2 is a schematic block diagram of a monitor coupled to the electrical power system of FIG. 1;

FIG. 3 is a plot showing an electrical waveform caused by a vegetation intrusion on a conductor in an electrical power system;

FIG. 4 is a plot of reactive power vs. time showing an unbalanced capacitor switching event;

FIG. 5 is a plot of reactive power vs. time showing a motor switching on event;

FIG. 6 is a plot of reactive power vs. time showing a normal capacitor switching off event;

FIG. 7 is a plot of reactive power vs. time showing a normal capacitor switching on event;

FIG. 8 is a plot of reactive power vs. time showing a capacitor restrike event;

FIG. 9 is an enlarged portion of the plot shown in FIG. 8;

FIG. 10 is a plot of reactive power vs. time showing a switch bounce event;

FIG. 11 is a plot of reactive power vs. time showing a reactive power imbalance event;

FIG. 12 is a plot of reactive power vs. time showing a capacitor overcurrent event;

FIG. 13 is a plot of reactive power vs. time showing a capacitor arcing contact event;

FIG. 14 is a plot of transient voltage instability caused by a capacitor arcing contact event;

FIG. 15 is a plot showing the recorded reactive power step size for a specific capacitor bank; and

FIG. 16 is a cluster chart of a reactive power step change amongst phases of a capacitor bank.

### DETAILED DESCRIPTION OF THE INVENTION

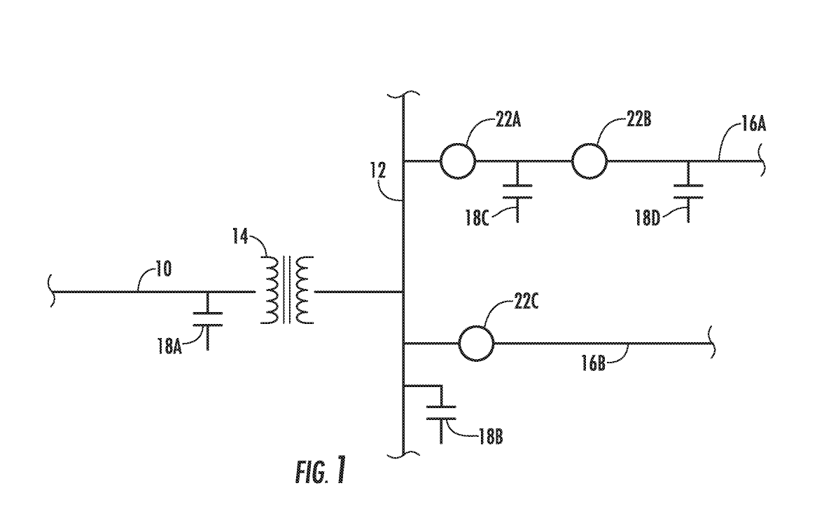

Referring to the drawings wherein identical reference numerals denote the same elements throughout the various views, a portion of an exemplary electrical power system is illustrated in FIG. 1. A transmission line 10 (which would connect to an upstream power generation station, not shown) is coupled to a distribution bus 12 through a substation transformer 14. One or more feeder lines 16 are coupled to the distribution bus 12. One or more electrical power users (not shown) are connected to the feeder lines 16. In the illustrated example only two feeder lines denoted 16A and 16B are shown.

Altogether, the transmission line 10, the distribution bus 12, and the feeder lines 16 illustrate a portion of an electrical utility's power system. As used herein, the term “line” refers to one or more conductors grouped together for conducting electrical power from a first point to a second point. As used herein, the term “conductor” refers to a material that provides a path for electricity and includes a wire, a group of wires, or other conductive material.

One or more capacitor banks, referred to generally at numeral 18, are connected to various portions of the electrical power system. It will be understood that each of the capacitor banks 18 is of conventional construction and incorporates one or more capacitors (i.e. typically one or more individual capacitor “cans” for each phase) and associated switching equipment for selectively coupling and decoupling the capacitors to the electric line. For the sake of illustrative simplicity the capacitor banks 18 are shown using standard circuit symbols. A first capacitor bank 18A is coupled to the transmission line 10. A second capacitor bank 18B is coupled to the distribution bus 12. Third and fourth capacitor banks 18C and 18D are coupled to the feeder line 16A.

Most typical power systems generate and distribute power using a three-phase system. Thus, the lines may deliver power over three conductors that each conducts a phase A, B, or C. The lines may also have a fourth conductor which is referred to as the neutral. For convenience, the power system illustrated herein is such a three-phase system that includes a neutral conductor.

One or more monitors, noted generally at 22, are provided on the electrical power system. It is noted that the method of the present invention need not include the monitors 22, but may instead be implemented as software and/or hardware which analyzes data provided from an outside source, such as existing measurement equipment. Monitors 22 may be used at any location within a system of power lines, i.e. generating stations, substations, transmission lines, primary and secondary distribution lines, and customer facilities. Furthermore, multiple data acquisition units 10 can be placed at selected locations of interest in a power system. By knowing the location of the monitors 22 and the layout of the power system, and by resolving whether capacitor activity is “upstream” or “downstream” of each of the individual monitors 22, the location of a monitored capacitor can be determined.

For example, as shown in FIG. 1, a first monitor 22A is positioned on the feeder line 16A between the distribution bus and the third capacitor bank 18C. A second monitor 22B is positioned between the third and fourth capacitor banks 18C and 18D. A third monitor is positioned on the feeder line 16B. The first monitor 22A would identify operation of the third and fourth capacitor banks 18C and 18D as taking place “downstream” of itself. It would identify the operation of the first or second capacitor banks 18A or 18B as not downstream of itself. The second monitor 22B would identify operation of the fourth capacitor bank 18D as taking place “downstream” of itself. It would identify the operation of the first, second, or third capacitor banks 18A, 18B, or 18C as not downstream of itself. The third monitor 22C would identify the operation of the first, second, third or fourth capacitor banks 18A, 18B, 18C, or 18D as not downstream to itself

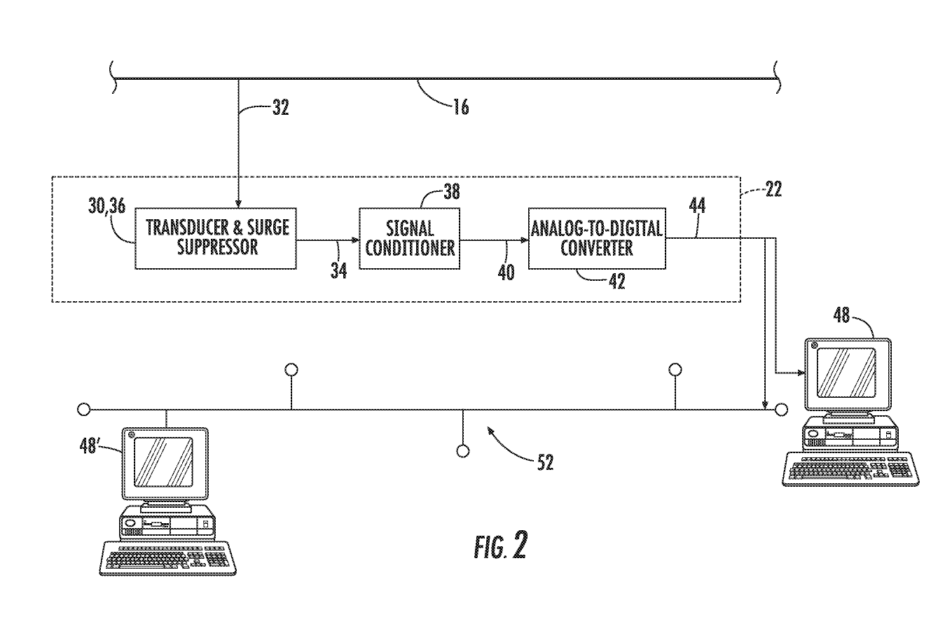

FIG. 2 illustrates the monitors 22 and associated equipment in greater detail. The monitor 22 includes a sensor or transducer 30, coupled to a line such as one of the feeder lines 16 shown in FIG. 1, as indicated schematically by line 32. The term “sensor” is broadly defined herein to include sensing devices, detecting devices, and any other structurally equivalent device or system understood to be interchangeable therewith by those skilled in the art. The illustrated transducer 30 senses or monitors several line parameters, such as line voltages for each phase (line-to-line V_{LL} or line-to-neutral V_{LN}), or load current I_{L} flowing through line 16 for each phase conductor or neutral conductor. Any subset of the 6 voltages or 4 currents measurable in a three-phase system may be monitored. The present invention may also be used with single-phase systems. For instance, in response to monitoring a load current I_{L} and a line-to-neutral (phase) voltage, transducer 30 produces a parameter signal, here, a signal 34 that is indicative of dual load current and phase voltage.

The transducer 30 may be a conventional transducer or an equivalent device, such as a multiple phase current measuring device typically having one current transformer per phase, plus one on the neutral conductor, of the feeder line 16, and a multiple phase voltage measuring device, measuring the line-to-neutral voltages for each phase of line 16. Moreover, the monitor 22 may receive transducer signals from already existing current and voltage sensors. For example, if only a single phase of the voltage is measured by transducer 30 or another transducer (not shown), the monitor 22 may be equipped with conventional hardware or software of a known type to derive the other two phases. That is, knowing one phase voltage on a three-phase system, the other two phases may be obtained by applying the appropriate plus/minus appropriate (e.g., 120⁰) phase shift to the monitored phase voltage. It is also conceivable that other parameters, e.g. power factor, of the power flowing through line 16 may be measured with suitable transducers.

The monitor 22 may also include surge protection, for example, a surge suppressor or protector 36. The surge protector 36 may be supplied either with the transducer 30, as illustrated, or as a separate component. The surge protector 36 protects the monitor 22 from power surges on the feeder line 12, such as those caused by lightning strikes or the like.

The monitor 22 may include a signal conditioner 38 for filtering and amplifying the signal 34 to provide a clean, conditioned signal 40. Preferably, the signal conditioner 38 includes one or more filters (e.g. low-pass, band-pass, high-pass, notch) for removing frequency components not of interest for the analysis such as signal noise. The monitor 22 may be used with a single frequency in the spectrum, or a combination of frequencies.

The signal conditioner 38 may also amplify the parameter signals 34 for the appropriate range required by an analog-to-digital (A/D) converter 42. For example, the current flowing on the power system 20 may have a dynamic range of 10 to 10,000 Amps, which transducer 30 may convert into a time-varying voltage signal of, for example, +/−25 volts, whereas the A/D converter 42 may accept voltages of +/−10 volts. In this case the signal conditioner 38 appropriately converts and scales these signals for conversion by the A/D converter 42 from an analog signal 40 into a digital parameter signal 44.

When the transducer 30 is an analog device, the monitor 22 includes the illustrated discrete A/D converter 42. The transducer 30 may also be implemented as a digital device which incorporates the signal conditioning function of conditioner 38 and the analog-to-digital conversion function of the A/D converter 42.

The digital parameter signal 44 is supplied to a computing device for analysis. An example of a suitable computing device includes a conventional microcomputer (sometimes referred to as a personal computer or “PC”). However, any device capable of executing a program instruction set to analyze the digital parameter signal may be used. An external computing unit 48′ may be connected to the monitor 22 using a direct connection such as a serial or parallel cable, wireless link, or the like. Furthermore, the monitor 22 may be connected to a remote computing unit 48″ through a network 52 e.g., a local area network (LAN), a wide area network (WAN), or the Internet. Also, it is noted that the analysis method described herein may be integrated into existing systems which already include data collection and/or processing capability. For example, known types of relays, power quality meters, and other equipment used in power transmission or distribution often contain microprocessor-based electronics suitable for performing the analysis.

The present invention provides a method for automatically identifying the normal and abnormal operations of capacitor banks on electric power systems by using characteristics or patterns in the measured signals and also of associating each operation with a particular capacitor bank whenever possible.

There are three significant steps involved in this process, which are: (1) Classification, in which classification algorithm(s) are used to analyze the collected data and determine if the data corresponds to a normal or abnormal capacitor operation; (2) Feature Extraction, wherein characteristic features are extracted from the data that would help to tie the data to a particular capacitor bank on the monitored line; and (3) Clustering and Identification, in which an automatic clustering algorithm is used to identify the capacitor bank that was involved in the operation based on the extracted features. These three steps will now be described in detail. The process may be carried out by computer software operating on one or more saved data files, for example files containing captures of the digital parameter signal 44 described above, and the process will be explained in that context.

### I. Classification of Capacitor Related Events

Due to the vast nature of electrical power systems, the amount of data collected while monitoring the system can be overwhelming. The data collected contains information pertaining to a wide range of events on the power system. Some of these are related to normal power system operations while others are due to failing components on the power system. It is important to first differentiate other normal and abnormal power system events from those involving capacitors (also called “capacitor events”). Once this determination is made, then the actual capacitor bank 18 involved in the operation can be identified using steps 2 and 3 mentioned above.

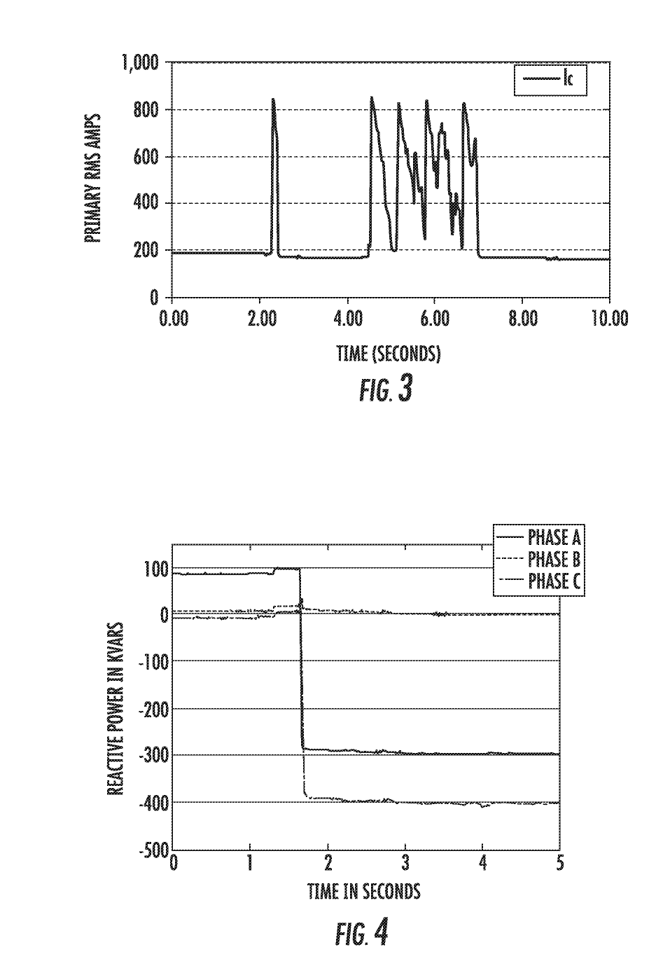

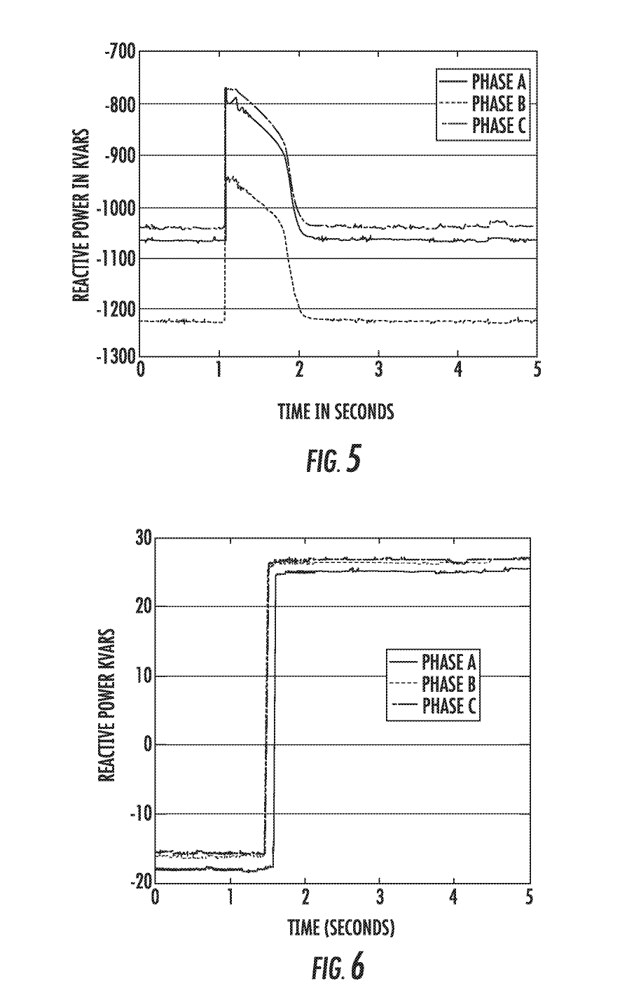

Different types of power system events have different identifying features which are observable, for example, in voltage or current plots. FIG. 3 shows an example of an observed current waveform from one instance of an overcurrent fault caused by vegetation intrusion; FIG. 4 shows reactive power values from an unbalanced capacitor switching on event; and FIG. 5 shows the reactive power values from an event where a motor started. It can be seen that not all events observed on the power system are capacitor related. In the above three examples, only the second example involved a capacitor. Based on the signal characteristics, a classification algorithm can be used to identify an event as capacitor related operation.

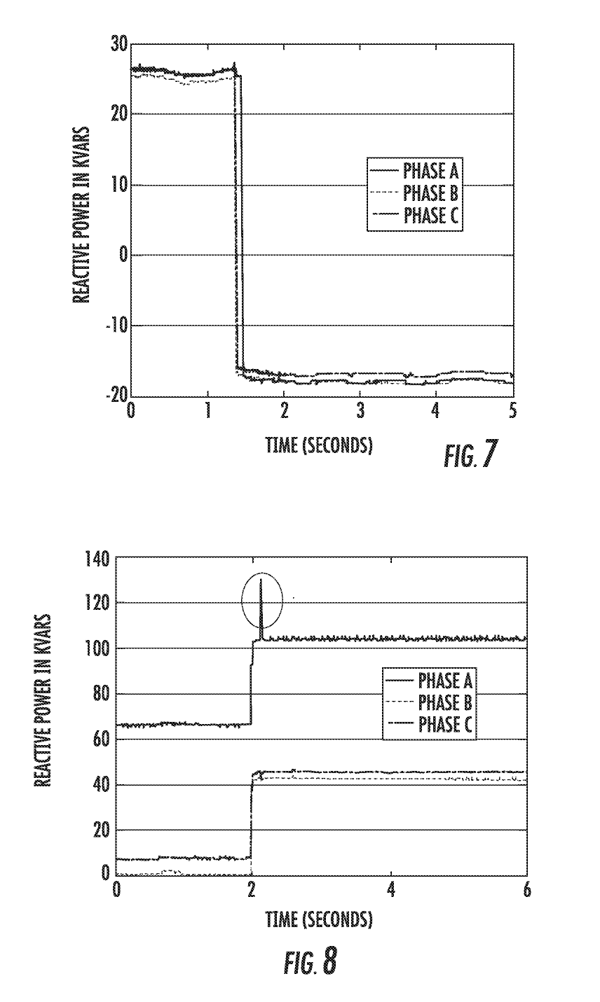

Different types of capacitor related operations may be observed on the power system. Some of these operations may be due to a healthy capacitor switching while others may be from capacitors that are failing or have already failed. FIGS. 6 and 7 show reactive power (VARS) observed when a healthy capacitor switches off and on the line being monitored, respectively. The step changes in VARS are a key feature that helps to identify capacitor events, as opposed to other power system events. Another key feature for identifying if the capacitor is healthy is that the step changes observed on all phases are of similar magnitude (i.e. balanced). Though these are key features, other features may also be used to determine capacitor operation.

Several abnormal capacitor operations corresponding to different failure modes have been observed and can be identified through features extracted from power system data. These examples, which are described below, are not an exhaustive list of all failure modes associated with capacitors.

### EXAMPLE 1

### Unbalanced Capacitor Operation

FIG. 4 shows an example of unbalanced capacitor switching on event. It can be seen that phase B VARS is flat while the other two phases show a step change. The unbalance is caused when one or more phases in a capacitor bank 18 fail to switch. Phases may not switch due to several factors including blown fuses, stuck switches, and the like.

### EXAMPLE 2

### Capacitor Restrike

Capacitor restrike may sometimes occur when de-energizing a capacitor bank 18 (capacitor switching off). When a capacitor is de-energized a voltage will remain trapped inside the capacitor and the capacitor will continue to maintain the voltage at this high value while the system voltage continues to decrease. When the voltage difference between the system voltage and the constant voltage at the capacitor exceeds the dielectric strength between the contact gap, insulation breakdown occurs, connecting the capacitor temporarily to the system. This will cause unwanted capacitor transients. Such restrikes degrade the life of the contacts. The transients may also affect other devices on the system. FIG. 8 shows a plot of VARS from a restrike during a capacitor switching off. The steps in VARS are similar to those observed during a normal capacitor switching off, except for the “spike” that is circled. This spike as caused by the capacitor restrike phenomenon. Note that the “spike” may be present either in current waveforms, voltage waveforms, or both.

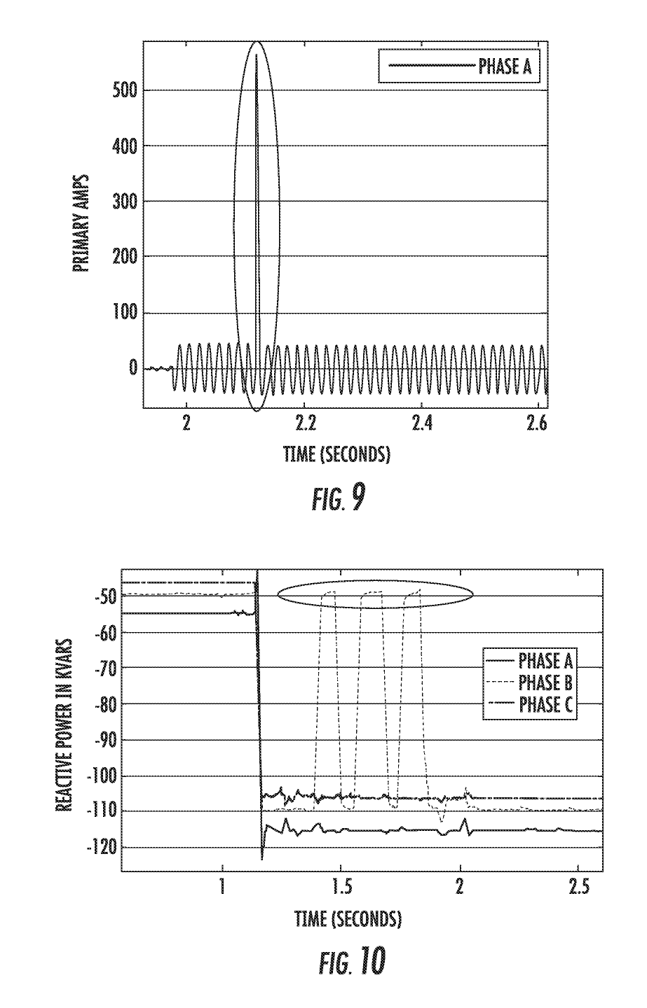

The “spike” may not always be as prominent as the above example on the VARS signal. A more sophisticated signal analysis method may be needed to detect the transient. FIG. 9 shows an enlarged portion of the phase A current signal of FIG. 8, after applying such a technique. The transient can be clearly seen. Various signal analysis techniques for detecting such transients are known.

### EXAMPLE 3

### Capacitor Switch Bounce

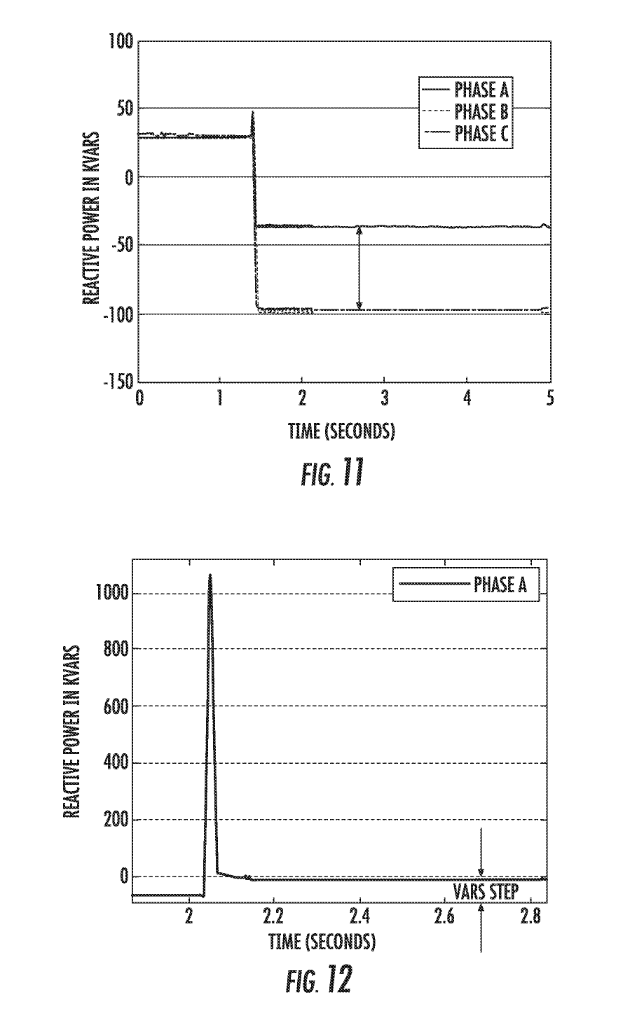

Most capacitor banks are switched on using mechanical contacts and hence are susceptible to “switch bounce”. When contacts are brought together their momentum and elasticity may cause them to rebound. The bounce, being oscillatory in nature, is the equivalent of switching the capacitor on and off multiple times. For a healthy switch, the bounce is very rapid and the amplitude is too small to produce any noticeable effects. However in the case of a faulty switch, the bounce is more noticeable. FIG. 10 shows the VARS from a capacitor switch bounce event.

Unlike the normal capacitor switching on example where phase B VARS would be expected to have a single drop, it can be seen that the phase B VARS go up and down five times. This is the result of the contact bounce. Since this is the equivalent of switching the phase B capacitor bank on and off multiple times, it leads to the rapid deterioration of the contacts. The transients introduced by these operations can also have adverse effects on other apparatus on the circuit. The “up and down” VAR characteristic can be used to detect capacitor switch bounce condition.

### EXAMPLE 4

### Reactive Power Imbalance

During normal capacitor operations, the VAR changes observed on all the phases are close to each other within a manufacturing tolerance. This is called a “balanced condition”. They are not exactly identical and can vary depending on temperature and load conditions. Depending on the VAR support needed, multiple capacitor cans are connected on each phase to achieve the desired VARS. For example, if 200 kVARS is needed per phase, it may be achieved by connecting two 100 kVAR capacitor cans on each phase. When one or more of these cans fail, the VARS supplied on each of the phases will no longer be the same causing an “imbalance”. The phase with the failed capacitor unit may not be able to provide the required VAR support. The VAR imbalance may also cause an imbalance on the line voltage. The VAR imbalance may be caused by a number of reasons. It is important that the problem is detected and fixed before it escalates to other failures. FIG. 11 shows the VARS plot corresponding to VARS imbalance condition. It can be seen that phase B and phase C step by 125 kVARS while Phase A steps only by 60 kVARS. Unlike the unbalanced condition explained earlier, the phase A VARS line is not totally flat. Here the reactive power imbalance is nearly 50%. A possible reason may be the failure of one of the individual capacitor units on phase A. Failure of the capacitor can on a particular phase also can cause the VAR step size for that phase to be larger than the VAR step size for the other, healthy phases.

### EXAMPLE 5

### Capacitor Overcurrent

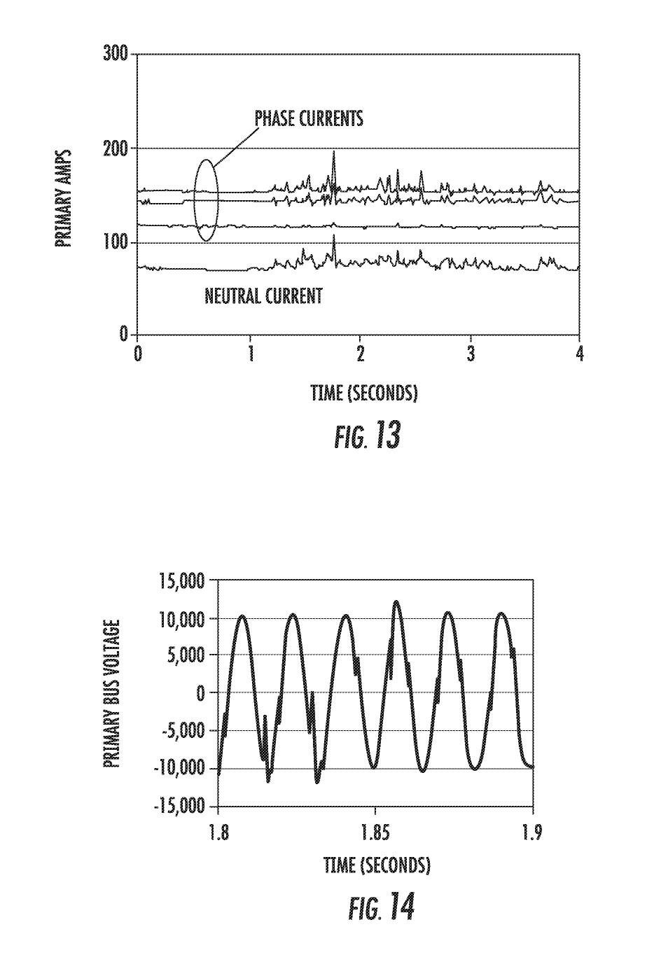

Capacitor units are often protected by internal or external fuse elements. In case of a short circuit due to a faulty unit, these fuses operate and isolate the faulty unit. The short circuit causes an overcurrent and blows the fuse. A short circuit also can occur because of a temporary condition, such as nearby lightning or a fault elsewhere on the system. A fuse also can operate if the fuse is slightly undersized, even if there is no fault or problem with the capacitor itself. The unit that was isolated will no longer provide the needed VARS support and hence a VAR imbalance will also be observed following the overcurrent. This characteristic can be used to identify capacitor overcurrent. Detection of the capacitor overcurrent is helpful in identifying the cause of a VAR imbalance condition. FIG. 12 shows the VARS from an instance of capacitor overcurrent on phase A. The overcurrent blew a fuse and after the overcurrent, a step increase in VARS can be seen. This was the result of losing a capacitor unit.

### EXAMPLE 6

### Arcing Capacitor Switch Contact

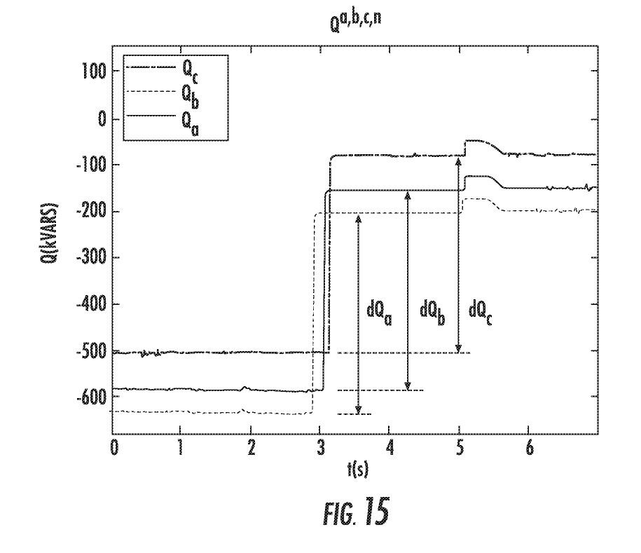

Capacitor switch contacts may deteriorate over time due to several factors such as repeated operations, corrosion etc. This process may be accelerated by other factors like repeated cycling because of a defective capacitor controller. When the capacitor switches on, the deteriorated contacts are no longer able to make proper connection and result in contact arcing. This is the equivalent of the contacts making and breaking connections several times per second. Since they connect and disconnect the capacitor, it introduces numerous voltage and current transients of significant magnitudes. This may not only severely damage the capacitor bank, but also affect other devices on the circuit and pose a power quality problem. FIG. 13 shows the Root Mean Square (RMS) currents from a capacitor switch contact arcing episode. FIG. 14 shows the voltage waveform from the same switch contact arcing episode. It can be seen that the transients caused by the arcing leads to a heavily distorted voltage waveform.

### EXAMPLE 7

### Excessive Capacitor Operations

Capacitor banks are often switched on or off automatically using capacitor controllers. Capacitor controllers may use one or more parameters including but not limited to line voltage, time of day and temperature measurement to decide whether to switch the capacitor bank on or off. Sometimes, a capacitor controller may misoperate because of several reasons like wrong settings, a defective component or due to some other condition existing on the circuit. The misoperating controller may cause the capacitor to repeatedly cycle, i.e. switch on and off numerous times far more often than expected or desired. This can cause power quality problems. If not fixed, abnormal wear and tear from excessive operations may cause failure of apparatus associated with the capacitor bank. For example, a capacitor bank switch or the capacitor itself may fail. Individual capacitor switching operations (normal or abnormal) can be identified as previously outlined. By counting the number of operations during a time period, it is possible to compare the number or frequency of capacitor operations to a predetermined standard, in order to determine if the number or frequency of operations is normal or excessive. Sophisticated techniques such as clustering may also be used to provide better estimates of the number of operations and to determine the specific bank that was misoperating. It is to be noted that while the individual operations seen independent of other operations may or may not be normal, but the repeated operations considered as a whole is abnormal.

Software may identify operational scenarios and classify them as normal or abnormal, for example, by using known waveform analysis or pattern-matching techniques to identify the data patterns and discrete waveform features detailed in the above examples and also other characteristics. The list of the types of normal and abnormal capacitor related operations that can be identified by the invention is not limited to these examples. Other specific normal and abnormal operations can be identified through empirical studies or through theoretical models.

### II. Feature Extraction

Once normal or abnormal capacitor related operations are identified and classified, the events may be “clustered” together by various features in order to determine whether the events are repetitive, as described in more detail below. In order to do this, features or attributes are extracted from individual data captures and comparisons are then made to all other captures on the same line in order to determine if similarities exist. Capacitor events have several features which are well suited for clustering, as they have very little variation from one event to the next for a given capacitor. The extracted features from the individual captures may be written to a data file for subsequent clustering.

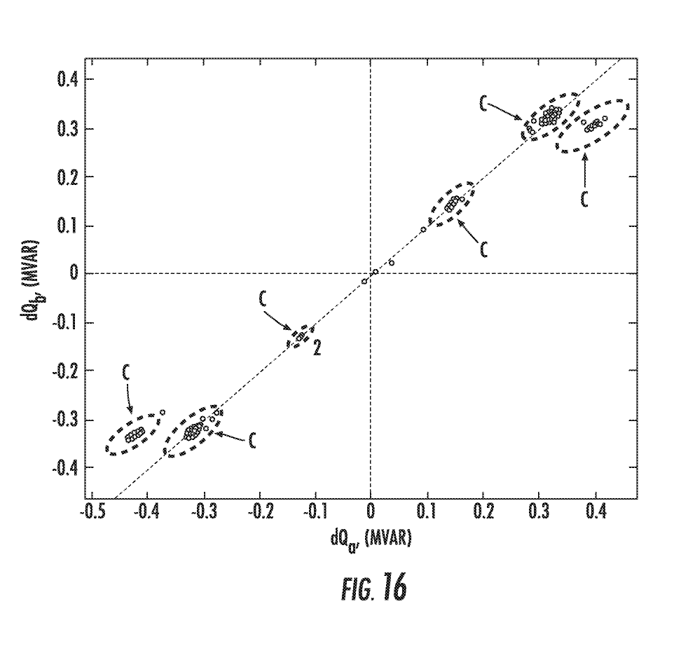

The main feature that is extracted is the reactive power (VARS) step size for each phase. Typically a capacitor bank 18 (see FIG. 1) will be rated at a specific VARS at a standard voltage and outside temperature. Changes in these variable factors will cause the actual VARS to vary. Generally, though, fixed factors such as individual construction differences and location within the power system produce a stronger relation than variable factors. Accordingly, the VARS step size is relatively consistent for a given capacitor bank, and provides a solid base for clustering, especially in cases where a feeder has multiple banks of differing size. For example two capacitor banks 18 of the same rated size, e.g. 400 VARS may actually have a capacity of 410 or 390 VARS. In cases where a feeder has multiple banks of similar size, the sequence in which the phases change (step up or down) and the amount of time between the changes for each phase may be is considered in order to give separation to the different banks. FIG. 15 is a plot showing the recorded step size for an example capacitor bank 18 with the values for change in reactive power for each phase dQa, dQb, and dQc labeled.

### III. Clustering and Identification of Capacitor Banks

Subsequent to the feature extraction, the clustering process begins by “plotting” the extracted features in the feature domain for each event. As used here, the term “plot” does not specifically require that a visual representation or graph be created, rather, it also encompasses mathematical and/or statistical analysis that is the equivalent thereto. In the case of a capacitor bank 18, the change in reactive power (dQ) for each of the three phases (dQai, dQbi, dQci), is plotted in three dimensions. Because of measurement error and small variations, events caused by the same device operating in the same way will produce slightly different “points” in this three dimensional feature space.

For example, consider a case where there are two different capacitor banks 18 on a given feeder, one where each dQ is approximately 900 kVAR, and one where each dQ is approximately 600 kVAR. If ten operations of each capacitor bank 18 were plotted, there would be ten dQa, dQb, and dQc values grouped around the point (600, 600, 600) and ten values grouped around the point (900, 900, 900). Known clustering algorithms are used to observe the three-dimensional distance between each point and attempt to group events that are relatively close to each other. By looking at the relative distances, the algorithm attempts to determine how many clusters are present in the given data, and both the center and radius of each individual cluster. These decisions are made by considering the number of events in the proposed cluster (a cluster of one event is not meaningful) as well as the radius of the cluster, which represents the similarity of the events in question (a cluster with a large radius may include several events not necessarily related to each other).

FIG. 16 shows an example where a clustering algorithm has found six clusters of events, marked at the arrows “C”. Each of the clusters is representative of a repetitive event at a particular capacitor bank 18. There are a few events in the center of the plot which do not cluster.

Problems can be encountered when there is not enough separation between groups to make a distinction between them. Consider, for instance, if there were two 600 kVAR banks instead of one 600 kVAR and one 900 kVAR bank. In that case, there would have been twenty points clustered around (600, 600, 600) and no way to distinguish which events belonged to which bank. In cases like this, the software considers additional features in order to distinguish between different capacitor banks 18. If, for instance, one bank switched in phase order A, B, C, and the second bank switched in order C, A, B, the switching sequence would be plotted as a fourth dimension. While the two 600 kVAR banks would not have sufficient separation in three dimensions, they would be completely separated in the fourth dimension, allowing for cluster identification. In the event that there is insufficient separation obtained by the addition of switching sequence, the relative switching times of the phases is used as a further means of discrimination. Suppose the first bank contained A switching followed immediately by B, with a two cycle pause between phases B and C. If another bank of similar size switched in the same order, but had all three phases switching almost simultaneously, there would be separation in the C phase switching time dimension, allowing the algorithm to correctly separate the clusters. Note that the relative importance of these different clustering features can be re-ordered.

Once identified, each of the clusters represents a specific capacitor bank 18 and shows whether it is operating normally or not. It some cases it may not be possible to definitively identify a single capacitor bank. However, the method described above is still useful in such cases to identify one or more capacitor banks as candidates which are potentially involved with a power system event. Providing information about a failed or failing capacitor bank is very useful in cases where the utility companies are otherwise unaware of their malfunction until maintenance time. It allows more efficient determination that a capacitor is malfunctioning and which capacitor bank it is, thereby allowing system operators or others to take corrective actions while minimizing adverse effects to customers, the system or personnel.

The foregoing has described a method and system for diagnosis and identification of remote capacitor banks on a power system. While specific embodiments of the present invention have been described, it will be apparent to those skilled in the art that various modifications thereto can be made without departing from the spirit and scope of the invention. Accordingly, the foregoing description of the preferred embodiment of the invention and the best mode for practicing the invention are provided for the purpose of illustration only and not for the purpose of limitation.

What is claimed is:

1. A method of evaluating one or more capacitor banks in an electrical power system, comprising:
(a) acquiring data representing a signal of interest of the power system, where the data describes a plurality of power system events; and
(b) based on one or more patterns contained in the data, identifying at least one of the power system events as being associated with a capacitor operation.

2. The method of claim 1 further comprising classifying the capacitor operation as normal or abnormal.

3. The method of claim 1 further comprising:
(a) extracting at least one feature characteristic of a capacitor operation from the data; and
(b) identifying one or more capacitor banks as potentially being involved in the at least one capacitor operation, based at least in part on the at least one extracted feature.

4. The method of claim 3 wherein the at least one extracted feature is a voltage transient consistent with capacitor bank switch contacts alternately making and breaking connection several times per second.

5. The method of claim 3 wherein the one or more capacitor banks includes at least one capacitor for each of a plurality of phases, and the at least one extracted feature is a volt-ampere reactive power step size for each phase that occurs during a capacitor operation.

6. The method of claim 3 wherein the capacitor bank includes at least one capacitor for each of a plurality of phases, and the at least one extracted feature is a sequence in which the phases switch on or off.

7. The method of claim 3 wherein the capacitor bank includes at least one capacitor for each of a plurality of phases, and the at least one extracted feature is a time interval between the phases when the phases switch on or off

8. The method of claim 3 wherein step (a) comprises extracting a plurality of features from the data, and step (b) comprises grouping the extracted features into one or more clusters, wherein each cluster represents a repeated event occurring at a specific capacitor bank.

9. The method of claim 1 wherein the data is taken from multiple geographic monitoring points in the electrical power system.

10. The method of claim 9 wherein the data includes information as to whether the power system events have occurred upstream or downstream relative to each of the monitoring points.

11. The method of claim 2 further comprising:
(a) counting the number of capacitor operations over a defined period of time;
(b) comparing the number of operations to a predetermined limit; and
(c) classifying the operations as abnormal if the predetermined limit is exceeded.

12. The method of claim 2 further comprising:
(a) measuring the frequency of capacitor operations over a defined period of time;
(b) comparing the frequency of operations to a predetermined limit; and
(c) classifying the operations as abnormal if the predetermined limit is exceeded.
